(19) United States
(12) Patent Application Publication
(10) Pub. No.: US 2021/0181453 A1
(43) Pub. Date: Jun. 17, 2021

(54) MOBILE SOLAR REFRACTION DEVICE

(71) Applicant: The Boeing Company, Chicago, IL (US)

(72) Inventors: Michael R. Zolnowski, St. Louis, MO (US); David P. Heck, St. Charles, MO (US)

(21) Appl. No.: 16/716,129

(22) Filed: Dec. 16, 2019

(51) Int. Cl. G02B 7/02; G02B 3/00; F21S 11/00; H02S 40/22; H02S 40/38; H02S 10/40; F24S 10/70

(52) U.S. Cl. CPC G02B 7/021; G02B 3/0006; F21S 11/002; G02B 2003/0093; H02S 40/38; H02S 10/40; F24S 10/70; H02S 40/22

(57) ABSTRACT

In one example, a mobile solar system includes a solar refraction device comprising a lens array assembly having a plurality of lens array sub-assemblies. The lens array assembly is configured to refract solar energy impinging on the lens array assembly to focus refracted solar energy at a plurality of focal points of the plurality of lens array sub-assemblies. Each focal point of the plurality of focal points corresponds to a corresponding lens array sub-assembly of the solar refraction device. The solar system further includes a frame supporting the solar refraction device above an underlying surface, and a mobility system coupled to the frame to provide for movement of the solar refraction device above and across the underlying surface.

### FIELD

The present disclosure is generally related to solar systems, and in particular, to refractive solar systems.

### BACKGROUND

Hydrocarbons are currently burned to produce energy for many purposes, including power generation and industrial processes. However, there is a desire to use renewable energy sources, such as solar energy produced by the Sun, for such processes as solar energy can be used to provide heating and illumination and to generate electrical energy. Photovoltaic cells, for example, are capable of converting solar energy into electricity. However, photovoltaic cells can exhibit relatively low energy conversion efficiency for a given application in view of the area occupied by the cells. As another example, solar light tubes can be used to convey light from rooftops into the core of a building. However, the amount of illumination provided by solar light tubes can be constrained by the available size of rooftop space and the size of building corridors through which the light tubes are routed. Solar energy devices used for generating heat can be similarly limited by available space within a given application. Due to these and other constraints, solar energy devices are often integrated with building facilities or other use environments as fixtures that are selected for a specific application.

### SUMMARY

In one example, a mobile solar system includes a solar refraction device comprising a lens array assembly having a plurality of lens array sub-assemblies. The lens array assembly is configured to refract solar energy impinging on the lens array assembly to focus refracted solar energy at a plurality of focal points of the plurality of lens array sub-assemblies. Each focal point of the plurality of focal points corresponds to a corresponding lens array sub-assembly of the solar refraction device. The solar system further includes a frame supporting the solar refraction device above an underlying surface, and a mobility system coupled to the frame to provide for movement of the solar refraction device above and across the underlying surface.

In another example, a refractive solar system includes a solar energy device, and a solar refraction device. The solar refraction device includes a lens array assembly having a plurality of lens array sub-assemblies that are configured to refract solar energy impinging on the lens array assembly to focus refracted solar energy at a plurality of focal points. Each focal point of the plurality of focal points corresponds to a corresponding lens array sub-assembly of the solar refraction device. The plurality of focal points of the solar refraction device are directed at the solar energy device.

In yet another example, a mobile solar system includes a solar refraction device comprising a lens array assembly having a plurality of lens array sub-assemblies. The lens array assembly is configured to refract solar energy impinging on the lens array assembly to focus refracted solar energy at a plurality of focal points of the plurality of lens array sub-assemblies in which each focal point of the plurality of focal points corresponds to a corresponding lens array sub-assembly. The mobile solar system further comprises a frame supporting the solar refraction device above an underlying surface that includes retractable feet, and an adjustment mechanism to provide for adjustment of at least two degrees of freedom of the solar refraction device. The mobile solar system further comprises a first mobility system including one or more wheels, one or more continuous treads, or a combination thereof coupled to the frame to provide power-assisted movement of the solar refraction system above and across the underlying surface.

### BRIEF DESCRIPTION OF THE DRAWINGS

FIG. 1 is a perspective back-view of an example of an implementation of a lens array assembly of a solar refraction device in accordance with the present disclosure.

FIG. 2 is a back-view of the lens array assembly shown in FIG. 1 in accordance with the present disclosure.

FIG. 3 is a perspective back-view of an example of an implementation of a lens array sub-assembly of the lens array assembly shown in FIGS. 1 and 2 in accordance with the present disclosure.

FIG. 4 is a perspective back-view of an example of an implementation of a single column array of lens panes of the lens array sub-assembly shown in FIGS. 1, 2, and 3 in accordance with the present disclosure.

FIG. 5A is a system view of an example of implementation of a refracting convex lens.

FIG. 5B is a system view of the single column array of lens panes shown in FIG. 4 in accordance with the present disclosure.

FIG. 6 is a perspective side-view of the lens array sub-assembly shown in FIG. 3 in accordance with the present disclosure.

FIG. 7 is a perspective back-view of another example of an implementation of a lens array assembly of the solar refraction device and a container in accordance with the present disclosure.

FIG. 8 is a system view of the solar refraction device shown in FIG. 7 in accordance with the present invention.

FIG. 9 is a perspective back-view of a plurality of solar refraction devices, as shown in FIGS. 7 and 8, utilized to heat or melt a material in accordance with the present disclosure.

FIG. 10 is a flowchart of an example of an implementation of a method performed by the solar refraction device shown in FIGS. 1-9 in accordance with the present disclosure.

FIG. 11 is a flowchart of an example of an implementation of a method performed in fabricating the solar refraction device in accordance with the present disclosure.

FIG. 12 is a system diagram of an example of an implementation of the solar refraction device utilized for powering a turbine in accordance with the present disclosure.

FIG. 13 shows an example system 1300 including a solar refraction device utilized for heating the contents of a pipe.

FIG. 14 shows an example solar refraction device forming a canopy, and a plurality of reflectors to reflect light that passes through the solar refraction device.

FIG. 15 shows the example solar refraction device of FIG. 7 used to direct refracted solar energy at an object.

FIG. 16 shows a schematic depiction of an example processing system that incorporates one or more solar refraction devices.

FIGS. 17-20 show example mobile solar systems that each comprises a solar refraction device.

FIG. 21 shows an example solar energy system including a solar refraction device that is configured to refract solar energy onto a solar power device.

### DETAILED DESCRIPTION

A solar refraction device (SRD) disclosed herein comprises a lens array assembly having a plurality of lens array sub-assemblies. The lens array assembly is configured to refract solar energy impinging on the lens array assembly to focus refracted solar energy at a plurality of focal points. Each focal point of the plurality of focal points corresponds to a corresponding lens array sub-assembly of the lens array assembly.

The plurality of focal points of the SRD can be positioned to illuminate or heat objects using the refracted solar energy or to concentrate the refracted solar energy at a solar energy device. Examples of solar energy devices that can receive and utilize the refracted solar energy concentrated by the SRD include solar lighting devices, solar heating devices, photovoltaic cells, etc. The act of heating an object includes increasing its temperature and/or changing its phase in various examples. Objects heated by an SRD can include materials in various forms as well as containers that are open face (e.g., a bin) and containers that partially or fully enclose the materials. In some embodiments, the container is in a closed configuration. In another embodiment, the container encloses contents that are in another enclosed container. Use of the phrase “in a closed configuration” hereinafter refers to the container that is being heated being partially or fully closed itself, or the container being open, partially closed or closed and the contents inside being enclosed in another container, object, housing or the like.

In this disclosure, materials heated by an SRD can include any type of material or combination of materials in solid, liquid, and/or gas forms. While liquids and gases are examples of fluids, such materials can include granulated solids that can be conveyed and/or mixed in a manner similar to a fluid. Examples of materials that can be heated include working fluids (e.g., water within heat exchangers, heat engines, vapor cycles, and other thermodynamic systems), industrial materials, such as metallic industrial materials including aluminum, steel, iron or other metals or alloys, non-metallic industrial materials such as plastics or other recyclable non-metals, chemicals, such as chemical reactants and chemical products (e.g., in a chemical processing system), foods, seeds, soil, crushed stone, sand, animal waste, compost, lumber, and other forms of organic matter.

In at least some examples, the SRD forms part of a mobile solar system, including a frame and a mobility system. The frame supports the solar refraction device above an underlying surface. The mobility system is coupled to the frame to provide for movement of the SRD above and across the underlying surface, thereby enabling the SRD to be transported to a location of operation. The mobile solar system can further include an adjustment mechanism configured to provide for adjustment of a roll, a pitch, and a yaw of the SRD, thereby enabling the SRD to be orientated relative to the Sun and for the solar energy refracted by the SRD to be directed at a target location or region.

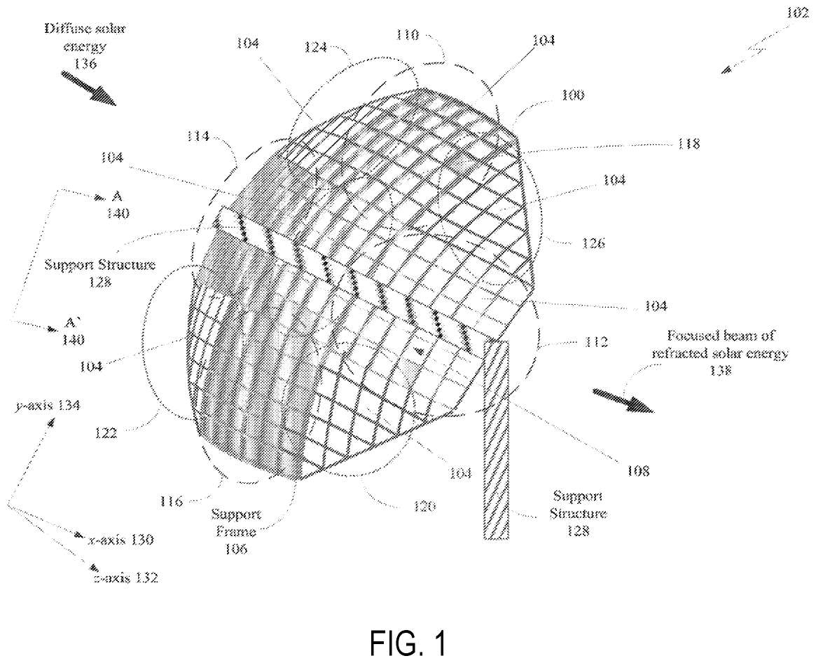

In FIG. 1, a perspective back-view of an example of an implementation of a lens array assembly 100 of an SRD 102 is shown in accordance with the present disclosure. SRD 102 includes the lens array assembly 100 and a plurality of lens panes 104 attached to the lens array assembly 100. In this example, the lens array assembly 100 can include a support frame 106 constructed of a rigid material such as, for example, a metal such as steel or aluminum or other rigid non-metallic materials (e.g., wood or composites). The support frame 106 can include a plurality of openings that are configured to accept the plurality of lens panes 104, which are each configured to be attached to the lens array assembly 100. The support frame 106 is constructed of a rigid material that is strong enough to support the weight of, and stresses caused by, the plurality of lens panes 104 placed within the plurality of opening in the support frame 106 and capable of withstanding prolonged exposure in the environment to things such as, for example, electromagnetic radiation, thermal heat, and ultraviolent radiation without significantly degrading or warping. The lens array assembly 100 includes an outside surface 108 that also corresponds to the outside surface of SRD 102, an inside surface (not shown), and a plurality of lens array sub-assemblies. In at least some examples, each lens array sub-assembly is a discrete panel of the lens array assembly 100. However, two or more lens array sub-assemblies can be integrated into a common panel in another example.

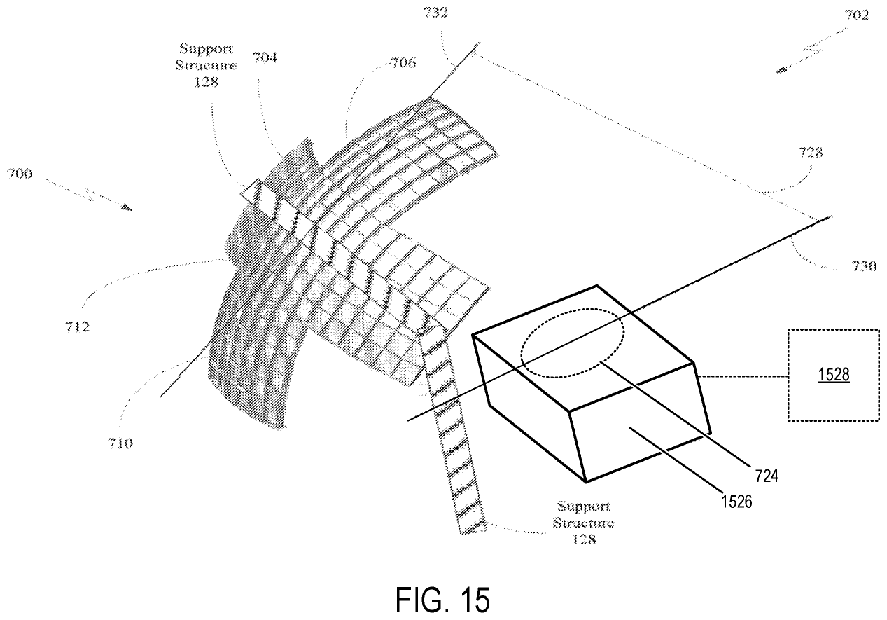

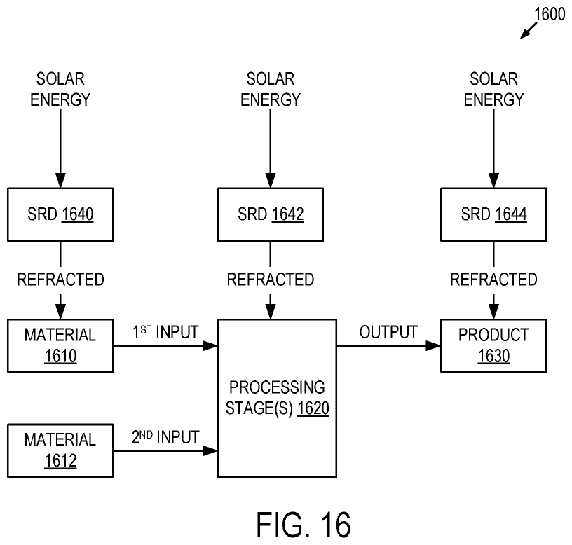

In this example, the lens array assembly 100 is shown having nine (9) lens array sub-assemblies 110, 112, 114, 116, 118, 120, 122, 124, and 126. Each lens array sub-assembly is shown having a sub-plurality of lens panes (from the total plurality of lens panes 104) attached to the corresponding lens array sub-assembly. As an example, part of a support structure 128 is also shown attached to one side of the lens array assembly 100. The support structure 128 can be attached to the support frame 106 in a way that allows the support structure 128 to maintain the lens array assembly 100 at a predetermined distance from an object to be illuminated or heated (e.g., a heating container or materials contained therein) where the predetermined distance is a distance that is based on the multiple focal lengths of the lens array assembly 100 (described in more detail later). The support structure 128 can be connected to, or part of, a solar tracker (not shown), where the solar tracker is configured to move the support structure 128 (and the as the lens array assembly 100) in a manner that maintains a high amount of solar energy being refracted through SRD 102 and focused at an illumination area where heating or other action of interest (e.g. photovoltaic conversion) occurs. In this disclosure, a “high” amount of solar energy is considered enough solar energy for SRD 102 to operate according to the present description. Similar to the support frame 106, the support structure 128 can be constructed of a rigid material that is strong enough to support the weight of, and stresses caused by, the lens array assembly 100. Support frame 106 can include metallic and non-metallic rigid materials. Furthermore, in this example, the lens array assembly 100 is shown to have a three-dimensional convex shape with each corresponding lens array sub-assemblies 110, 112, 114, 116, 118, 120, 122, 124, and 126 also being convex. In an example, the three-dimensional convex shape is approximately parabolic along the x-axis 130 and z-axis 132 and also along the y-axis 134 and z-axis 132. However, lens array assembly 100 may have other suitable three-dimensional shapes, including a trough shape, such as depicted in FIGS. 13 and 14, as examples. In an example of operation, SRD 102 refracts diffuse solar energy 136 (i.e., the impinging solar energy) that impinges on the outside surface 108 (of both SRD 102 and lens array assembly 100) through SRD 102 resulting in a focused beam of refracted solar energy 138 that is focused in a direction along the z-axis 132 away from the inside surface of the lens array assembly 100.

In this example, it is appreciated by those of ordinary skill in the art that only nine (9) lens array sub-assemblies 110, 112, 114, 116, 118, 120, 122, 124, and 126 have been shown in FIG. 1 for purpose of illustration. However, the lens array assembly 100 can include more or less lens array sub-assemblies based on design and application of SRD 102. As will be described later, in general each lens array sub-assembly will produce a corresponding focused beam of refracted solar energy that will have a focal length that corresponds to the specific lens array sub-assembly. The resulting focal lengths from the different lens array sub-assemblies can be different from each other so that the combined focused beams of refracted solar energy (for each lens array sub-assembly) combines to form the focused beam of refracted solar energy 138 that produces an illumination area (described later) that is located at a distance from the SRD. In at least some examples, an illumination area is distributed over a region of an object to heated, rather than being focused at a same location. The SRD can include or can be utilized in combination with an adjustment mechanism configured to adjust a position of each of one or more lens array sub-assemblies, thereby enabling the focal points of refracted solar energy provided by the lens array sub-assemblies to be adjusted in relation to each other. In an example, the adjustment mechanism can include a hinge located at an interface between two lens array sub-assemblies that enables one of the sub-assemblies to be rotated relative to the other sub-assembly. For example, the support structures and/or frames disclosed herein can provide rigid support to an SRD in each of two or more configurations, thereby enabling the various lens array sub-assemblies to be adjusted in relation to each other to achieve a desired configuration that is maintained by the support structure and/or frame.

From the detail in FIG. 1, in this example, SRD 102 is shown to have an octagon two-dimensional convex shaped lens array assembly 100. Additionally, the lens array assembly 100 is shown to have five (5) rectangular shaped two-dimensional convex lens array sub-assemblies 110, 112, 114, 116, and 118 and four (4) triangular shaped two-dimensional convex lens array sub-assemblies 120, 122, 124, and 126. Moreover, each rectangular shaped two-dimensional convex lens array sub-assemblies 110, 112, 114, 116, and 118 is shown to have 8 by 8 (i.e., 64) lens panes (or plurality of openings for 64 lens panes) and each triangular shaped two-dimensional convex lens array sub-assemblies 120, 122, 124, and 126 is shown to have 28 lens panes (or plurality of openings for 28 lens panes) and eight (8) half-sized lens panes (or plurality of openings for 8 half sized lens panes). This results in SRD 102 having, in this example, a total of 432 lens panes and 32 half sized lens panes. Each of the lens panes of the plurality of lens panes 104 can be flat lens panes approximating a parabolic shape in the corresponding lens array sub-assembly based on the size and number of the discrete flat lens panes in the lens array sub-assembly or actual convex shaped lens panes. Furthermore, each lens pane can be made from glass, acrylic, or other suitable material. Moreover, each lens pane can be a flat or sloped lens pane or a Fresnel lens such that SRD 102 can be assembled from a combination of flat lens panes, sloped panes, and Fresnel lenses. In general, the lens panes can be removable and interchangeable within the lens array assembly 100. Furthermore, to make SRD 102 more dynamic, individual controls (not shown) can be installed in sections of the lens array assembly 100 or each opening that is configured to receive a lens pane in the lens array assembly 100 such that the controls are able to adjust the position of the individual panes to adjust the focus of SRD 102. Again, the octagon two-dimensional convex shape of the lens array assembly 100 is an example for illustration purposes and can be a different shape based on the design of the lens array assembly 100. FIGS. 13 and 14, for example, depict SRDs having different shapes from SRD 102.

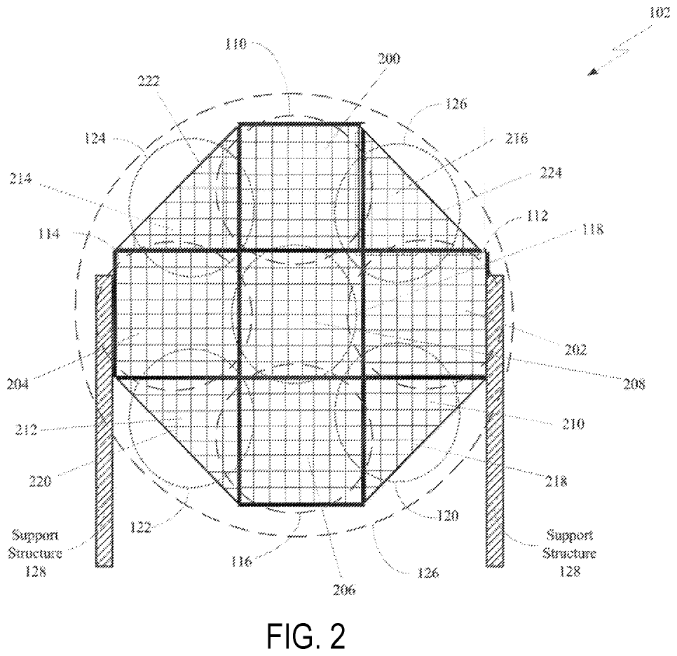

Turning to FIG. 2, a back-view of the lens array assembly 100, shown in FIG. 1 along viewing plane A-A′ 140, is shown in accordance with the present disclosure. FIG. 2 illustrates the relationship of the plurality of sub-assemblies 110, 112, 114, 116, 118, 120, 122, 124, and 126 and plurality of lens panes 104 in relationship with the lens array assembly 100. As described earlier, in this example, the lens array assembly 100 has an octagon shape and includes five rectangular shaped lens array sub-assemblies 110, 112, 114, 116, and 118, respectively, and four triangular shaped lens sub-assemblies 120, 122, 124, and 126, respectively. In this example, as described earlier, the five rectangular shaped lens array sub-assemblies 110, 112, 114, 116, and 118 include 64 lens panes designated by 200, 202, 204, 206, and 208, respectively. Similarly, the four triangular shaped lens array sub-assemblies 120, 122, 124, and 126 include 28 lens panes designated by 210, 212, 214, and 216, respectively, and 8 partial sized lens panes 218, 220, 222, and 224, respectively. If the four triangular shaped lens array sub-assemblies 120, 122, 124, and 126 are generally equivalent to half of a rectangular shaped lens array sub-assemblies, then the four triangular shaped lens array sub-assemblies 120, 122, 124, and 126 act as the equivalent of two rectangular shaped lens array sub-assemblies. In this case, the lens array assembly 100 can be described as having a total of seven (7) rectangular shaped lens array sub-assemblies instead of nine (9). As a result, the SRD 100 would have a total of 448 lens panes attached to the lens array assembly 100.

In general, the amount of energy produced by SRD 102 is directly related to the amount or intensity of solar energy incident upon the SRD, the location/positioning where the SRD will be utilized, and the array size of lens array assembly 100. For example, the higher the concentration of sunlight, the higher the amount of energy that is produced by SRD 102 for a given size of the lens array assembly 100. Specifically, according to the National Renewable Energy Laboratory (“NREL”) average data from 1998 to 2009, areas within the United States such as Arizona and parts of California, Nevada, New Mexico, Colorado, and Hawaii receive as an annual average over 7.5 Kilowatt hours (“KWh”) per square meter (m2) per day of concentrated solar power (“CSP”) that is available for use by solar systems.

Generally, the amount of solar energy which falls on the Earth in any a calendar year dwarfs the total energy output of all the world's fossil fuels used in world's industries. For example, the State of Kentucky receives about 3.75 kW/m2 of solar energy per day from the Sun and higher energy areas, such as Hawaii, receive about 5.75 kW/m2 of solar energy per day. Only a fraction of these totals are used for creating useable energy with the current solar cells because, current commonly used solar cells generally only reach about 18% energy conversion due to losses of heat, reflection angle, and electricity transfer.

As such, utilizing Hawaii as an example for melting aluminum, a 6 foot by 6 foot (i.e., an area of about 4 m2) lens array sub-assembly 110, 112, 114, 116, and 118 would be able to focus about 4 KWh of solar energy such that lens array assembly 100 would be able to focus at least 28 KWh of solar energy taking into account the five (5) rectangular shaped lens array sub-assemblies 110, 112, 114, 116, and 118 and four (4) triangular shaped lens array sub-assemblies 120, 122, 124, and 126. Assuming, 85% efficiency in this example, SRD 102 would be capable of melting about 74 pounds of aluminum per hour.

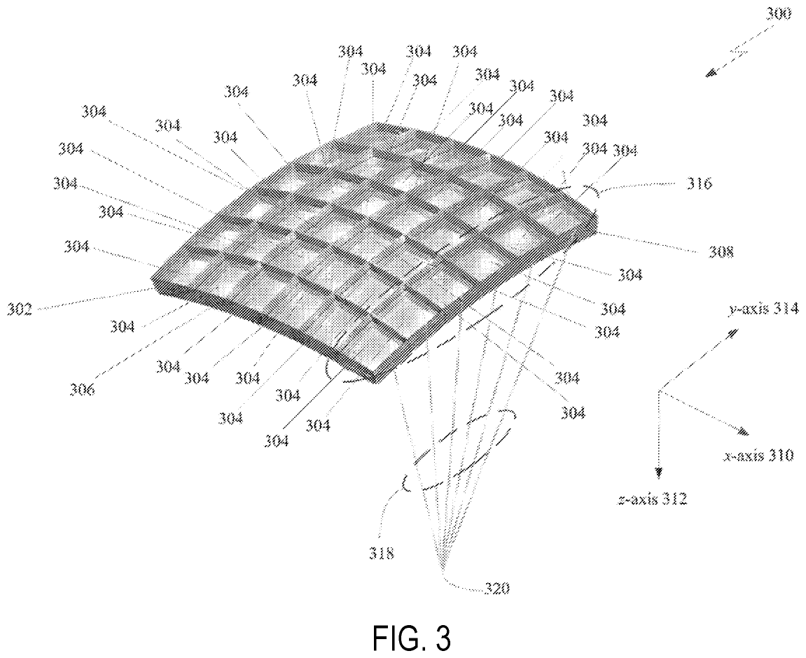

In FIG. 3, a perspective back-view of an example of an implementation of a lens array sub-assembly 300 of the lens array assembly 100 (shown in FIGS. 1 and 2) is shown in accordance with the present disclosure. The lens array sub-assembly 300 is show including a support frame 302 and approximately 36 lens panes 304 organized in six (6) rows and six (6) columns. The reason for only showing six (6) columns and rows in this example is for convenience of illustration since every lens pane 304 is being shown within a support frame of the lens array sub-assembly 300. The support frame is shown having a first side 306 and a second side 308. In this example, the convex curvature of the first side 306 of the support frame is shown along the x-axis 310 and z-axis 312. Similarly, the convex curvature of the second side 308 of the support frame is shown along the y-axis 314 and z-axis 312. As described earlier, the convex curvature can be approximately parabolic for both the first and second sides 306 and 308 of the support frame. If approximately parabolic, the lens array assembly 100 will produce a more focused beam of refracted solar energy 138 because in general a parabola is a special curve that has the mathematical relationship where all points of the parabola are an equal distance away from both a fixed line (mathematically referred to as the directrix) and a fixed point (mathematically referred to as the focus of the parabola, which is not to be confused with other instances of the term focus utilized in the present disclosure in connection with light or refracted solar energy).

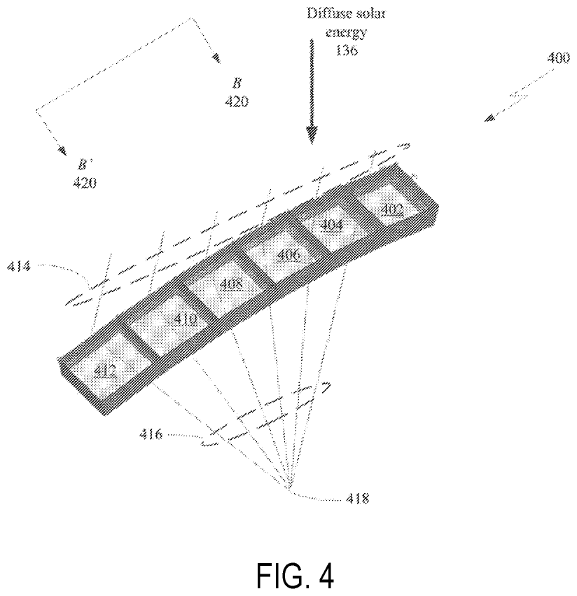

Additionally, in FIG. 3, the panes 304 of a first column 316 of panes 304 is shown receiving diffuse solar energy and focusing 318 it to a focal point 320. More specifically, turning to FIG. 4, a perspective back-view of an example of an implementation of a single column array of lens panes 400 of the lens array sub-assembly shown 300 (shown in FIG. 3) is shown in accordance with the present disclosure. In this example, the single column array of lens panes 400 includes six (6) lens panes 402, 404, 406, 408, 410, and 412. As an example of operation, the single column array of lens panes 400 is configured to receive a portion 414 of the diffuse solar energy 136 that impinges on the outside surface of the SRD and refract that portion 414 through the lens panes 402, 404, 406, 408, 410, and 412 to produce a focused beam 416 of solar energy that is focused to focal point 418.

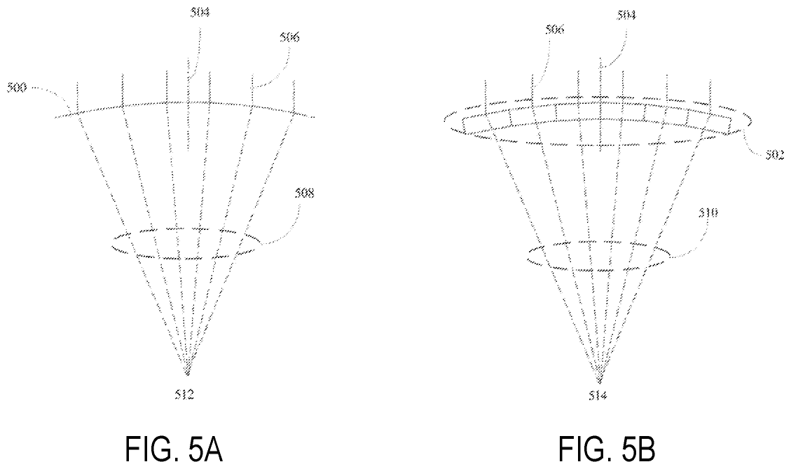

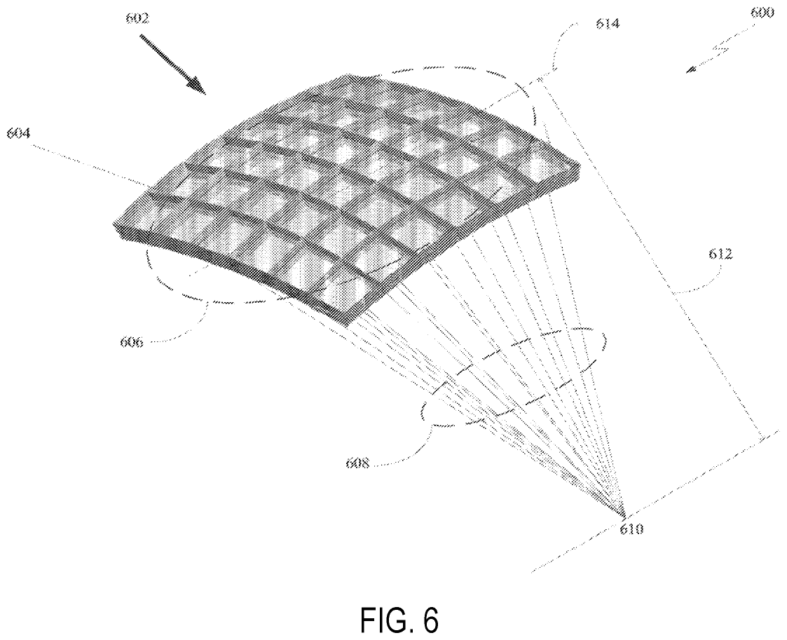

To further explain this example, in FIGS. 5A and 5B, system views of a continuous refracting convex lens 500 and of the single column array of lens panes 502 (shown in FIG. 4 cut along plane B-B′ 420) are shown along a center line 504. In both examples, impinging diffuse solar energy 506 is refracted and focused 508 and 510 to focal points 512 and 514, respectively. As a result, in operation, the discrete refracting convex lens created by the single column array of lens panes 502 focuses 510 the refracted solar energy to approximately the same focal point 514 as the focal point 512 of the continuous refracting convex lens 500.

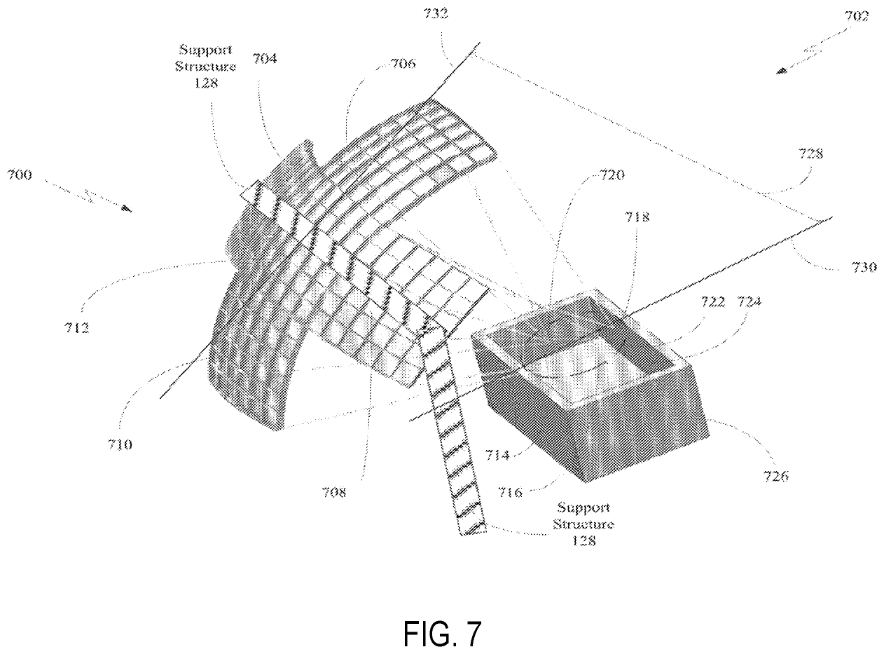

In FIG. 6, a perspective side-view of a lens array sub-assembly 600 (shown in FIG. 3 as lens array sub-assembly 300) is shown in accordance with the present disclosure. In contrast to FIG. 3, in FIG. 6, an example of operation is shown where diffuse solar energy 602 impinges on an outside surface 604 of lens array sub-assembly 600 that includes a plurality of lens panes 606. Each lens pane of the plurality of lens panes 606 then refracts a portion of the diffuse solar energy 602. In this example, all of the refracted beams from the plurality of lens panes 606 are focused 608 into a focal point 610 that is utilized to illuminate or heat an object (not shown). Within FIG. 6, the focal length 612 of the lens array sub-assembly 600 is shown as the distance between the focal point 610 and a centerline 614 of the lens array sub-assembly 600. This focal length 612 is based on the design of the lens array sub-assembly 600. Turning back to FIGS. 1 and 2, it is noted that there are multiple lens array sub-assemblies 110, 112, 114, 116, 118, 120, 122, 124, and 126 that each have their own corresponding focal length. Additionally, these multiple focal lengths can be equal or not equal to each other based on the design of the SRD for illuminating or heating an object. By having different focal lengths or different focal points for each lens array sub-assembly 110, 112, 114, 116, 118, 120, 122, 124, and 126, the lens array assembly 100 focus the diffused solar energy over a region rather than an individual point. This allows SRD 102 to illuminate or heat an object at an illumination plane by distributing the focused solar energy over a region of the illumination plane. If solar energy refracted by the SRD is overly focused rather than being distributed over a region, the refracted solar energy can damage or burn the object being illuminated or heated, which can include the container or materials contained therein.

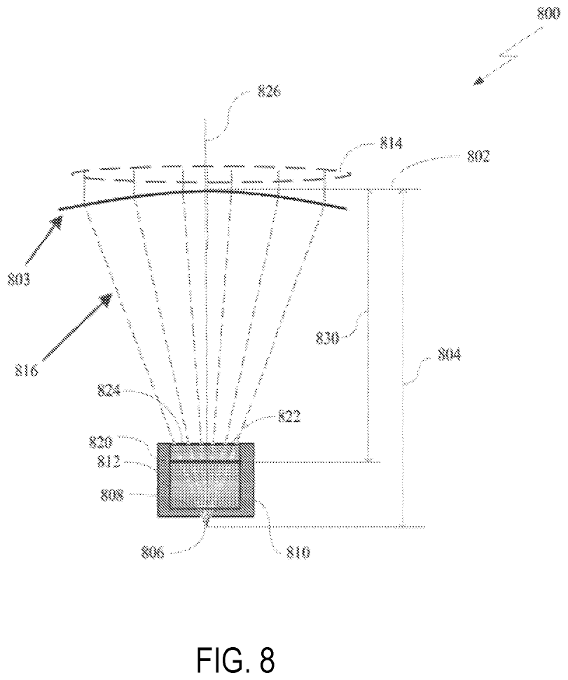

Expanding on this in FIG. 7, a perspective back-view of another example of an implementation of a lens array assembly 700 of the SRD 702 is shown in accordance with the present disclosure. In this example, the lens array assembly 700 is shown having five (5) rectangular shaped lens array sub-assemblies 704, 706, 708, 710, and 712, respectively. Additional triangular shaped lens array sub-assemblies can be added as described earlier, however, in this example only five (5) rectangular shaped lens array sub-assemblies 704, 706, 708, 710, and 712 are shown for the purpose of illustration. In this example, the lens array assembly 700 is shown having five different focal lengths or focal points 714, 716, 718, 720, and 722 for the individual lens array sub-assemblies 704, 706, 708, 710, and 712. The resulting focal points define an illumination area 724 within an open face container 726 (e.g., a materials bin, a crucible, etc.). It will be understood that container 726 is merely one example of a container that can be used to heat materials. In the example of FIG. 7, illumination area 724 is defined in size and shape by the plurality of focal points 714, 716, 718, 720, and 722 so that the illumination area is within a region bounded by the container or region of an objected to be illuminated by refracted solar energy. However, in the example of FIG. 7, the illumination area also sufficiently distributed to avoid excessive heating that can damage or exceed the operating parameters of the object being illuminated.

Additionally, shown in this example is a schematic representation of support structure 128 that can be used to support lens array assembly 700. In this example, the illumination area 724 is shown to be a predetermined distance 728 from the lens array assembly 700. Specifically, the predetermined distance 728 is defined as the distance 728 between a centerline 730 of the plane of the illumination area 724 and another centerline 732 of lens array assembly 700. The predetermined distance 728 is generally related to the focal lengths of the individual lens array sub-assemblies 704, 706, 708, 710, and 712 that produce respective focal points 714, 716, 718, 720, and 722 that define illumination area 724. As a result, the predetermined distance 728 is based on the design of the lens array assembly 700, because the focal lengths are based on the design of the lens array sub-assembly 700. In an example, support structure 128 is configured to maintain this predetermined distance 728 between the lens array assembly 700 and the illumination area 724 within container 726. As such, since the type of material, thickness, position, and angle of the lens panes within each lens array sub-assemblies 704, 706, 708, 710, and 712 determines the corresponding focal points 714, 716, 718, 720, and 722, it is appreciated that the type of material, thickness, position, and angle of the lens panes within each lens array sub-assemblies 704, 706, 708, 710, and 712 can be designed or otherwise selected such that they produce the corresponding focal points 714, 716, 718, 720, and 722 at the predetermined distance 728 and desired arrangement.

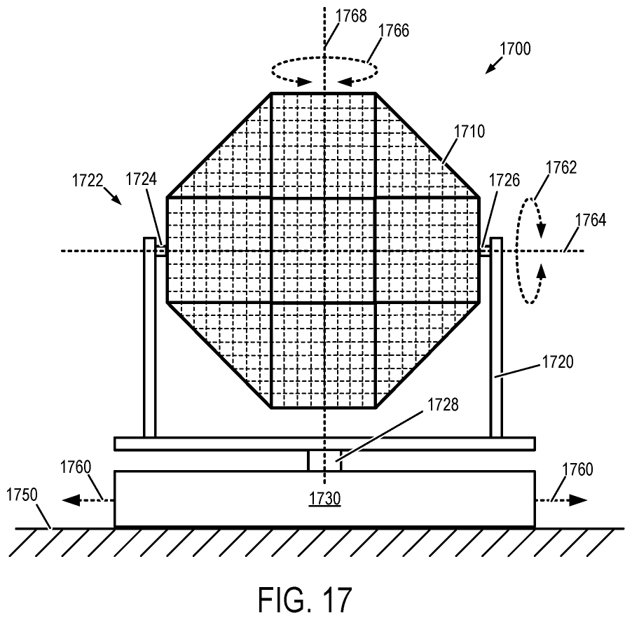

FIG. 15 shows the example SRD 702 of FIG. 7 used to direct refracted solar energy at an object 1526. Object 1526 may refer to any of the materials or containers disclosed herein that are to be heated by refracted solar energy, or may refer to a solar energy device that receives concentrated solar energy that is refracted by the SRD. As an example, FIG. 15 shows SRD 702 being used to heat object 1526 as a container that encloses contents (e.g., one or more materials) within the container (e.g., a closed container). It will be understood that object 1526 is depicted schematically in FIG. 15, and that object 1526 can take any suitable form. For example, a material that forms an underlying surface (e.g., a road bed being constructed) may be heated by solar energy refracted by SRD 702. In this example, illumination area 724 previously described with reference to FIG. 7 is instead provided at an exterior surface of object 1526 by refracted solar energy to heat the object and any contents enclosed therein.

As another example, object 1526 takes the form of a solar energy device. Examples of solar energy devices that can receive and utilize the refracted solar energy concentrated by the SRD include solar lighting devices (e.g., passive solar light tubes, fiber optics, etc.), solar heating devices (e.g., solar water heaters), and photovoltaic cells. Where object 1526 takes the form of a set of photovoltaic cells, in some examples object 1526 may be electrically coupled to one or more batteries 1528 to provide electrical charging of the one or more batteries using the refracted solar energy for energy storage and potentially later use. Alternatively or additionally, photovoltaic cells can provide electrical energy generated from refracted solar energy to an electrical grid or electrical circuit. The SRD, solar energy device, and associated components (e.g., batteries 1528) can collectively form a solar energy system.

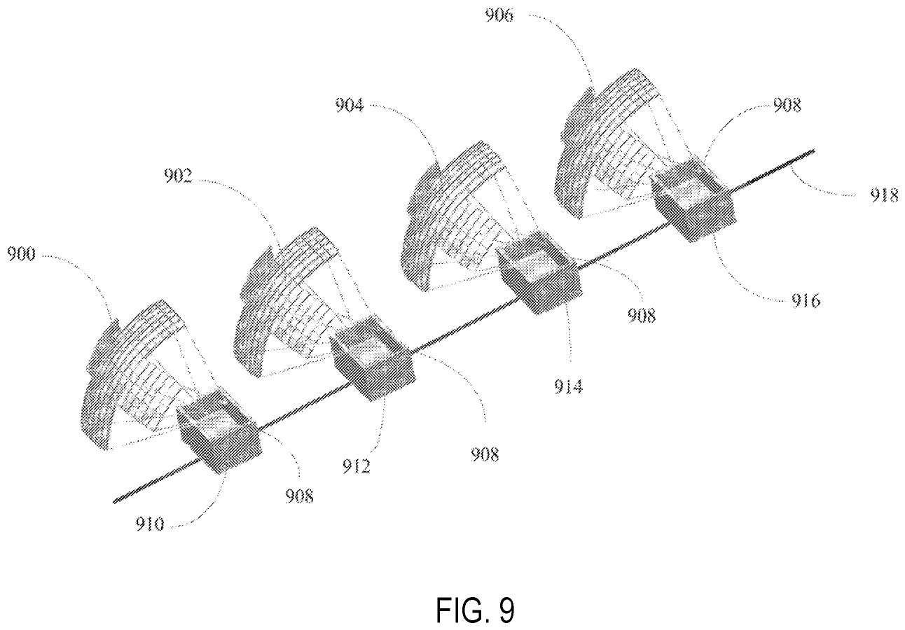

In FIG. 8, a system view of an SRD 800 is shown in accordance with the present disclosure. In this example, a centerline 802 is shown for equivalent lens 803 of plurality of lens panes of SRD 800. SRD 800 is shown to have a focal length 804 that extends to a focal point 806 past the bottom 808 of container 810. As an example of operation, container 810 contains a material 812 to be melted such as, for example, aluminum. The impinging diffuse solar energy 814 is refracted by the plurality of lens panes of the SRD 800 to form a plurality of refracted solar beams 816 (also known as rays) that are focused to focal point 806 past the bottom 808 of container 810. Since, container 810 contains material 812, the focused refracted solar beams 816 cannot concentrate their combined energy at focal point 806 and instead impinge on material 812 at an illumination plane 820. In this example, illumination plane 820 corresponds to the fill line of material 812 in container 810. Since illumination plane 820 corresponds to an illumination area 822 at opening 824 of container 810, the resulting heat generated by the focused refracted solar beams 816 is distributed over illumination area 822. In an example, area 822 is defined as a relatively small area compared to the size of SRD 800. By properly designing or otherwise positioning SRD 800 relative to an object to be heated or otherwise illuminated, illumination area 822 receives the proper amount of energy from SRD 800 with respect to the object (e.g., material 812 in this example) within suitable parameters. In this example, SRD 800 provides the greatest intensity of refracted solar energy along centerline 826, with the refracted solar energy being more diffuse moving outwards from the centerline 826. As such, the greatest intensity of heat energy provided by refracted solar energy within illumination plane 820, within this example, is at the intersection of illumination plane 820 with centerline 826. Intensity of the heat provided by the refracted solar radiation diminishes, in this example, as distance increases from centerline 826 within illumination area 822. As described earlier, the focal length 804 is related to the predetermined length 830 between centerline 802 of equivalent lens 803 to the container 810, where the predetermined length 830 is the length from the centerline 802 to illumination plane 820.

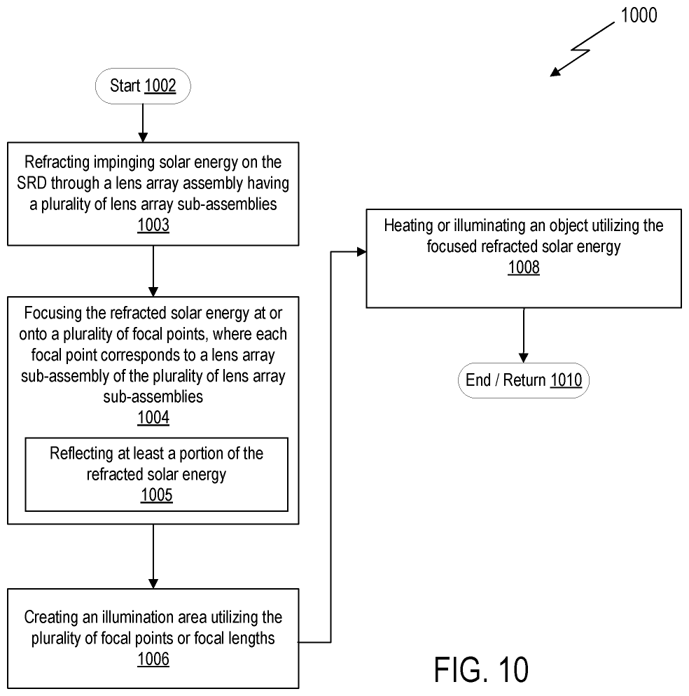

In some cases, an individual instance of SRD 800 is not sufficient to generate enough energy to heat an object to a desired state or to process a series of objects within a given time period. In these cases, multiple SRDs can be utilized together (e.g., in a chain) to increase the available heat energy or to increase a quantity of objects that can be heated within a given time period. In FIG. 9, a perspective back-view of a plurality of SRDs 900, 902, 904, and 906 are shown in accordance with the present disclosure. In this example, SRDs 900, 902, 904, and 906 are utilized to melt an industrial material 908 in a plurality of containers 910, 912, 914, and 916, respectively. In this example, the multiple SRDs 900, 902, 904, and 906 can be positioned by any known solar tracking system to collect the optimal quantity of solar light during the day. To maintain the optimal energy focusing of the SRDs 900, 902, 904, and 906, the containers 910, 912, 914, and 916 can be moved from one SRD to the next via a track system 918. In this example, the track system 918 is configured to input or extract a given container 910, 912, 914, and 916 at any point during a heating or illumination process (e.g., to remove melted or heated material and input new materials for processing).

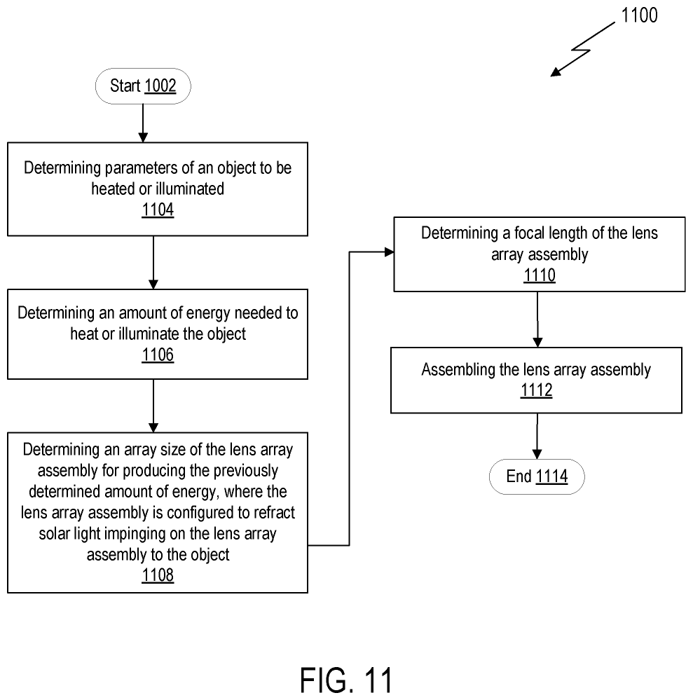

Turning to FIG. 10, a flowchart 1000 of an example method performed by or with respect to an SRD is shown in accordance with the present disclosure. The SRD of flowchart 1000 can refer to any of the example SRDs disclosed herein. In one example, the method includes heating an object, such as a material or container that contains one or more materials, with solar energy refracted by the SRD. The container can be open faced as depicted in FIG. 7 or can be a closed container that encloses the materials within the container as depicted in FIG. 15. As another example, method 1000 of FIG. 10 can be utilized to direct refracted solar energy at an illumination area with respect to an object, such as a solar energy device.

The method starts at 1002 by, in step 1003, refracting solar energy impinging on the SRD through a lens array assembly having a plurality of lens array sub-assemblies and, in step 1004, focusing the refracted solar energy onto a plurality of focal points. Each focal point of the plurality of focal points corresponds to a corresponding lens array sub-assembly of the plurality of lens array sub-assemblies. In at least some examples, at least a portion of the refracted solar energy can be reflected at 1005. FIG. 14 depicts an example in which reflector are used to reflect some of the refracted solar energy provided by an SRD.

In at least some examples, each focal point can be spaced apart from each other focal point of the plurality of focal points to define an illumination area to which refracted solar energy is to be directed. In these examples, the method at 1006 includes creating an illumination area with respect to an object to be heated (e.g., upon an exterior surface of the container or within the container) utilizing the plurality of focal points as defined, at least in part, by their respective focal lengths. As another example, at 1006, an illumination area is created with respect to an object, such as a solar energy device. In step 1008, the object is heated or illuminated utilizing the focused refracted solar energy. For example, a material or contents of a container (e.g., containing one or more materials) are heated at the illumination area utilizing the focused refracted solar energy. As another example, a solar energy device (e.g., a photovoltaic panel) is illuminated at the illumination area utilizing the focused refracted solar energy. At 1010, the method ends or returns to the start at 1002.

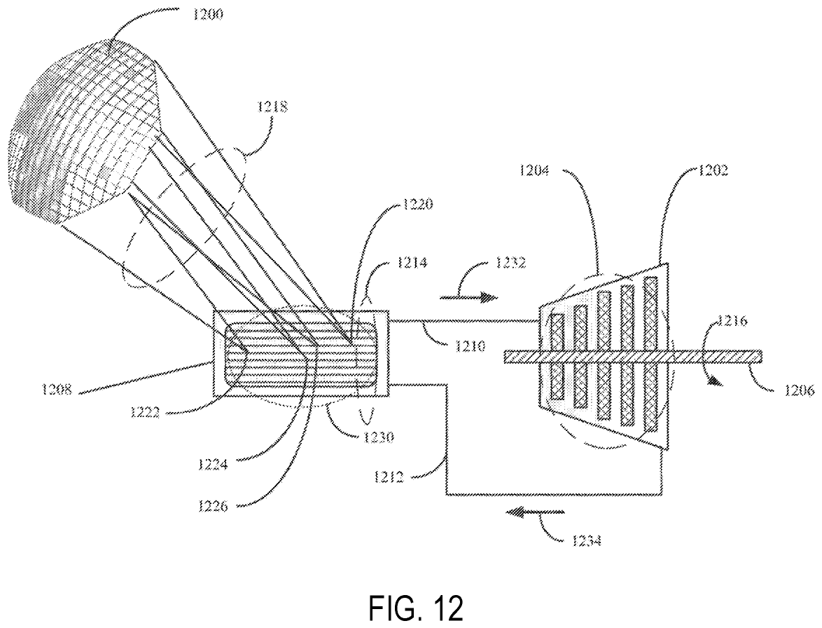

In FIG. 11, a flowchart 1100 of an example method performed in fabricating an SRD is shown in accordance with the present disclosure. Beginning from 1102, the method at 1104 includes determining parameters of an object to be heated or to which refracted solar energy is to be directed (e.g., in the case of a solar energy device). For example, the method at 1104 can include determining a size, shape, mass, composition, reflectivity, specific heat, flow rate (e.g., in material flow applications) and initial conditions (e.g., temperature, pressure, phase, etc.) for materials to be heated. Where the object further includes a container within which the materials are to be heated, the method at 1104 can include determining a size, shape, mass, composition, reflectivity, specific heat, and initial conditions for the container. As another example, where refracted solar energy is to be directed at a solar energy device, a solar energy usage rate or capacity of the solar energy device may be determined at 1104.

The method at 1106 includes determining an amount of energy needed to heat the object to a desired temperature and/or phase within a defined time period based on the parameters determined at 1104. As an example, to melt aluminum, an SRD might need to provide approximately 30,000 watts of refracted solar energy to melt about 100 pounds of aluminum per hour. As another example, where refracted solar energy is to be directed at a solar energy device, the parameters determined at 1104 may be used to determine the amount of energy needed to be generated by the SRD.

The method at 1108 includes determining an array size for the lens array assembly for producing the previously determined amount of energy for a given density of solar energy impinging on the lens array assembly. As previously discussed, the lens array assembly is configured to refract solar light impinging on the lens array assembly to the object being heated. As an example, in Hawaii the Sun produces about 1,000 watts per square meter so the lens array assembly needs to be approximately 30 m2 (i.e., about 6 meters by 6 meters).

The method at 1110 determines a focal length of the lens array assembly based on the geometry of the lens array assembly. The method at 1112 includes assembling the lens array assembly. The method then ends at 1114. In this example, assembling the lens array assembly can include assembling a plurality of lens array sub-assemblies and attaching the plurality of lens array sub-assemblies to form the lens array assembly, where each lens array sub-assembly has a corresponding focal length. As previously discussed, each lens array sub-assembly has a convex shape in at least some examples. Assembling the lens array assembly includes attaching a plurality of lens panes to each plurality of lens array sub-assemblies. In one example, the lens panes include Fresnel lenses. Moreover, assembling the lens array assembly also includes a first lens array sub-assembly with a different corresponding focal length than a second focal length corresponding to a second lens array sub-assembly of the lens array assembly. However, some or all of the lens array sub-assemblies of an SRD can have the same focal length in another example.

It will be appreciated by those of ordinary skill in the art that the examples of an SRD disclosed herein can be used to heat materials contained within an enclosure to increase the temperature of the materials or to change the phase of the materials (e.g., from solid to liquid or from liquid to vapor). For example, an SRD can be used to heat a fluid contained within a container such as an enclosed pipe, pressure vessel or other enclosed vessel, furnace, reactor, etc. The container can form part of a chemical processing system, electro-chemical processing system, oil refinery, food processing system, power plant, industrial boiler, physical plant (e.g., radiative heating), heating system (e.g., HVAC), sanitation system, etc. In at least some examples, the fluid can include an intermediate working fluid (e.g., water) that is used to transfer heat to a heat sink. In examples where an intermediate working fluid is used, this intermediate working fluid can provide power to machinery (e.g., turbines) or heat to another system or material (e.g., chemicals, foods, fossil fuels, etc.). In another example, a container can take the form of an open face bin for holding materials, such as depicted in FIG. 7.

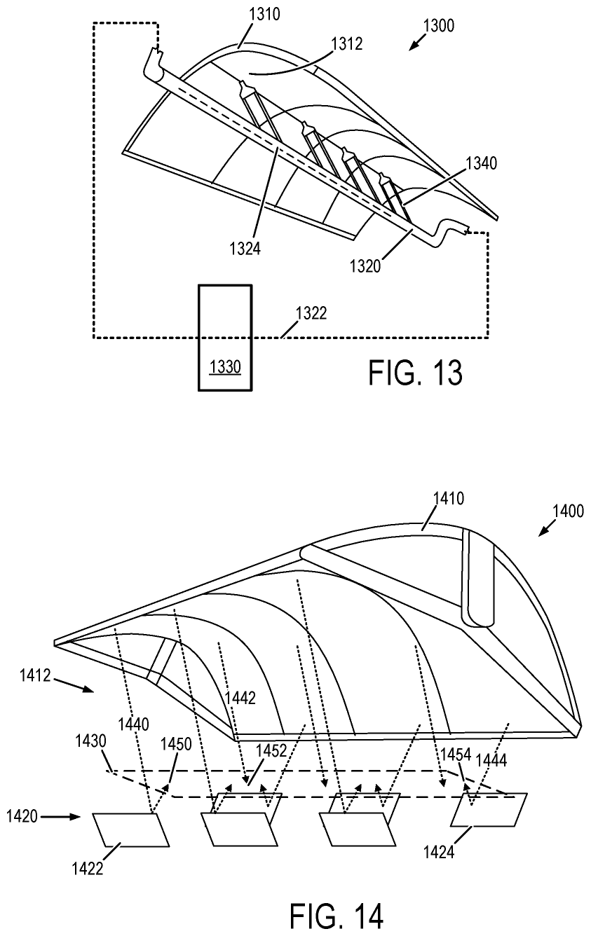

Turning to FIG. 12, a system diagram of an example of an implementation of the SRD 1200 utilized for powering a turbine 1202 is shown in accordance with the present disclosure. The turbine 1202 can include a plurality of turbine blades (also known as vanes) 1204 and a shaft 1206. In this example, the turbine 1202 is connected to a container 1208 via at least an inflow tubular pipe 1210 and outflow tubular pipe 1212. Container 1208 includes a plurality of pipes 1214 within container 1208 that are configured to be heated by the SRD 1200. Pipes 1214 can be filled with a fluid such as, for example, a gas (such as, for example, air), steam, water, or other heatable fluid that is capable of being heated in container 1208 and passed to the turbine 1202. Turbine 1202 is a rotary machine that extracts energy from the resulting fluid flow and converts it into useful work energy that rotates 1216 shaft 1206. In an example of operation, the SRD 1200 receives solar energy and focuses at 1218 refracted solar energy towards pipes 1214 of container 1208. As previously discussed, multiple focal points 1220, 1222, 1224, and 1226 can be focused at 1218 towards the container 1208 to define an illumination area 1230 with respect to container 1208. The fluid in the pipes 1214 is then heated up and heated fluid passed to the turbine 1202 via inflow tubular pipe 1210 in the direction of 1232. The heated fluid turns the turbine blades 1204 resulting in the shaft 1206 rotating 1216 along its axis. The exhausted fluid is returned to container 1208 via the outflow tubular pipe 1212 in the direction of 1234. It is appreciated by those of ordinary skill in the art that other industrial heating examples can be implemented by utilizing the SRD 1200 as a heating device for other materials.

FIG. 13 shows an example solar heating system 1300 including an SRD 1310 and a pipe segment 1320 that can be heated by solar energy refracted by SRD 1310. SRD 1310 can incorporate any of the SRD configurations disclosed herein, including a lens assembly having a plurality of lens array sub-assemblies in which each lens array sub-assembly provides a corresponding focal point of refracted solar energy that is positioned to heat the contents enclosed within pipe segment 1320. Pipe segment 1320 is one example of a container for contents to be heated by an SRD. Within the context of a container that encloses contents, the focal points of refracted solar energy provided by SRD 1310 can be positioned at a surface of the container (e.g., an exterior of pipe segments 1320).

In this example, pipe segment 1320 forms part of a pipe system 1322 represented schematically in FIG. 13 that contains a flow of contents. For example, pipe system 1322 can form a closed loop containing a material (e.g., a fluid such as a liquid or gas, or granulated solids). Accordingly, pipe system 1322 is one example of an enclosed container that can be heated by an SRD. Pipe system 1322 can be connected to one or more system components 1330 represented schematically in FIG. 13 such that pipe segment 1320 is in fluid communication with the system components. In an example, pipe system 1322 in combination with system components 1330 forms a closed loop containing a material (e.g., a fluid or granulated solids). Accordingly, pipe system 1322 in combination with system components 1330 is another example of an enclosed container that can be heated by an SRD.

System components 1330 can include one or more mechanical conveyance machines (e.g., a pump or auger conveyor) to convey or circulate a material within the pipe system 1322 in a particular flow direction. System components 1330 can include one or more heat sinks that extract heat from a material contained within pipe system 1322. Examples of heat sinks include mechanical machines (e.g., turbines) that extract heat energy from a material and convert that heat energy into work, heat exchangers, or other materials to be heated.

In the example depicted in FIG. 13, SRD 1310 has a curved shape within a plane that is orthogonal to a longitudinal axis 1324 of pipe segment 1320. Surface 1312 of SRD 1310 that faces pipe segment 1320 forms an interior of the curved shape. System 1300 includes a support structure 1340 in this example. For example, support structure 1340 supports SRD 1310 relative to pipe segment 1320. However, pipe segment 1320 and SRD 1310 can be separately supported in other examples. It will be understood that SRD 1310 can have other suitable shapes and configurations from the example depicted in FIG. 13 to heat enclosed containers, including pipe systems that convey materials along a flow direction.

FIG. 14 shows an example solar heating system 1400 including an SRD 1410 and one or more reflectors 1420 (e.g., mirrors) positioned to reflect at least a portion of refracted solar energy 1412 received from the SRD toward an object 1430. SRD 1410 can incorporate any of the SRD configurations disclosed herein, including a lens assembly having a plurality of lens array sub-assemblies in which each lens array sub-assembly provides a corresponding focal point of refracted solar energy that is positioned to illuminate or heat object 1430. In the example depicted in FIG. 14, SRD 1410 forms a canopy and has a curved shape. Thus, SRD 1410 can shield object 1430 from precipitation or other contaminants in addition to providing refracted solar energy for illumination or heating. Object 1430 can refer to any of the containers or materials disclosed herein that is illuminated or heated by an SRD.

One example of reflectors 1420 is depicted at 1422 reflecting a first portion 1440 of refracted solar energy 1412 received from SRD 1410 toward object 1430. For example, this first portion 1440 of refracted solar energy 1412 can be focused at a first focal point that is positioned to illuminate or heat object 1430 at a first location 1450. FIG. 14 further depicts a second portion 1442 of refracted solar energy 1412 received from SRD 1410 being focused at a second focal point that is positioned to illuminate or heat object 1430 at a second location 1452. In this example, the second portion 1442 of the refracted solar energy is not reflected by a reflector. Reflectors 1420 can be used to reflect different portions of the refracted solar energy received from SRD 1410 to the same focal point or to different focal points that are spaced apart from each other. A second example of reflectors 1420 is depicted at 1424 reflecting a third portion 1444 of refracted solar energy 1412 received from SRD 1410 toward object 1430. In this example, the third portion 1444 of the refracted solar energy is focused at a third focal point that is positioned to illuminate or heat object 1403 at a third location 1454 that is spaced apart from locations 1450 and 1452.

Reflectors, such as example reflectors 1420, can be used to direct refracted solar energy to different regions of an object, including regions that reside outside of the optical path of the refracted solar energy emitted from surfaces of the SRD. For example, as depicted in FIG. 14, reflectors can be used to direct refracted solar energy to an underside or side regions of object 1430. In these examples, reflectors can be arranged around or partially beneath the object being illuminated or heated. Reflectors 1420 can be flat or curved, including reflectors that have a planar reflective surface, a convex reflective surface (e.g., semi-circular or parabolic as viewed in cross-section), or a concave reflective surface (e.g., semi-circular or parabolic as viewed in cross-section).

The use of reflectors with an SRD has the potential to increase heating efficiency or illumination intensity with respect to an object (e.g., a solar device) by using refracted solar energy that would otherwise not come into contact with the object. For example, reflectors can be configured to accommodate variations in an angle of the refracted solar energy as the Sun transits the sky. Additionally or alternatively, the use of reflectors with an SRD has the potential to more evenly illuminate or heat an object over its various surfaces. Reflectors can be positioned at fixed positions and orientations relative to an SRD or to an object to be illuminated or heated by the SRD. However, in at least some examples, reflectors are moveable (e.g., by electromechanical actuators) in one or more degrees of freedom (e.g., translation and/or rotation relative to one, two, or three axes) to enable the reflectors to accommodate a variety of lighting conditions, illumination or heating scenarios, and object configurations.

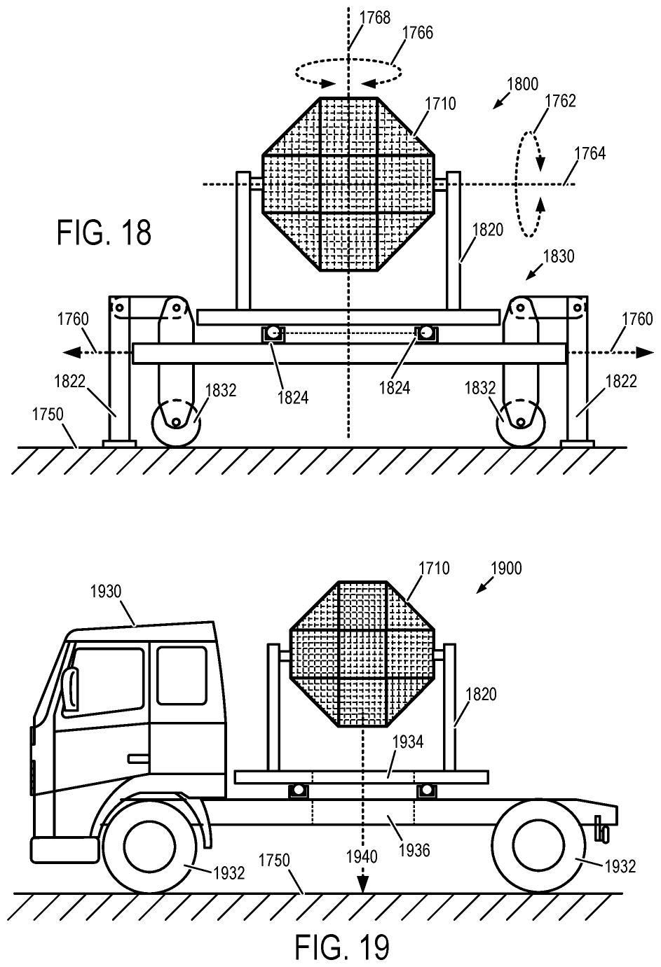

FIG. 16 shows a processing system 1600 that incorporates one or more SRDs 1640, 1642, 1644, etc. at various stages of a manufacturing process. The SRDs in this example include any of the example SRDs disclosed herein. As one example, solar energy refracted by SRD 1640 is used to heat a first material 1610 that is then provided as a first input to a set of one or more processing stages 1620. Material 1610 can be heated by SRD 1640 within an enclosed container or other container, for example. As depicted in FIG. 16, additional materials (e.g., material 1612) can be provided as additional inputs to the one or more of processing stages 1620 where materials 1610, 1612, etc. are combined to form a product 1630 as an output of the processing system. Solar energy refracted by SRD 1642 can be used to heat any combination of materials during the one or more processing stages 1620. Solar energy refracted by SRD 1644 can be used to heat product 1630 that is output from the one or more processing stages 1620. Product 1630 can also be heated within an enclosed container or other container, for example. Further, solar energy can be used to heat any transport lines or tubes between the starting material container(s), processing stage(s), and product container(s). Processing system 1600 may represent any suitable type of processing systems. Examples include, but are not limited to, chemical processing systems (e.g. a refinery or other chemical plant), food processing systems (e.g. a food product manufacturing facility), and waste processing systems.

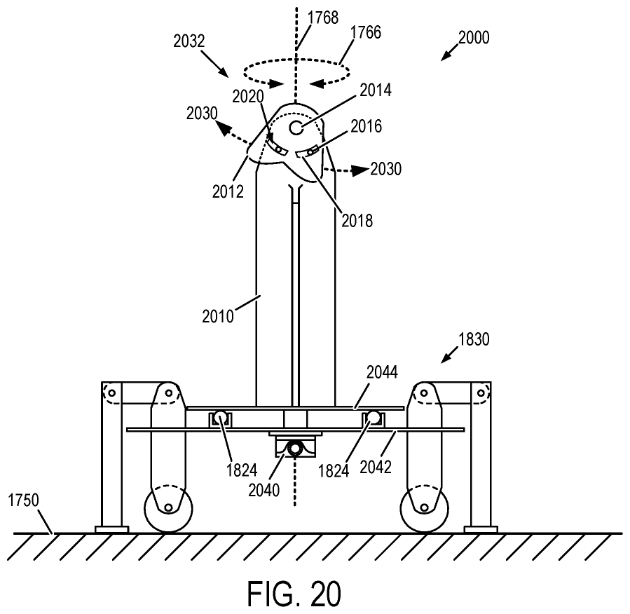

FIG. 17 shows an example mobile solar system 1700 that includes an SRD 1710, a frame 1720, and a mobility system 1730. SRD 1710 can incorporate any of the SRD configurations disclosed herein. In an example, SRD 1710 comprises a lens array assembly having a plurality of lens array sub-assemblies configured to refract solar energy impinging on the lens array assembly to focus the refracted solar energy at a plurality of focal points in which each focal point corresponds to a corresponding lens array sub-assembly of the SRD.

Frame 1720 is attached to mobility system 1730, represented schematically in FIG. 17. Frame 1720 is configured to be removably attached to mobility system 1730 in at least some examples. In a terrestrial-based example, frame 1720, alone or in combination with mobility system 1730, supports SRD 1710 above an underlying surface 1750. FIGS. 18 and 19 depict further examples of solar system 1700 in which mobility system 1730 includes wheels that contact underlying surface 1750. In an example, mobility system 1730 represented schematically in FIG. 17 may refer to one or more wheels, one or more continuous treads (e.g., of a tread vehicle), or a combination of one or more wheels and one or more continuous threads. In other examples, mobile system 1730 may take the form of an aerial vehicle or a vehicle that utilizes magnetic levitation. In some examples, mobility system 1730 comprises a motor or other suitable drive system components to provide power-assisted movement of the SRD above and across underlying surface 1750. For example, mobility system 1730 may take the form of a motorized vehicle, such as a land-based road vehicle, rail-based vehicle, construction vehicle, etc., a watercraft, an aerial vehicle, or other suitable type of vehicle. Mobility system 1730 is coupled to frame 1720 to provide for movement of SRD 1710 above and/or across underlying surface 1750, enabling SRD 1710 to be transported to a location of operation. In the example depicted in FIG. 17, system 1700 enables SRD 1710 to be moved relative to underlying surface 1750 in one, two, or three degrees of freedom. For example, mobility system 1730 enables SRD 1710 to move 1760 (e.g., translate) relative to underlying surface 1750. In another example, the mobility system is non-motorized (such as in the case of a trailer or a railcar), and includes a hitch or mechanical coupling that enables the SRD to be towed by another vehicle across underlying surface 1750.

Additionally, in the example depicted in FIG. 17, frame 1720 includes an adjustment mechanism 1722 to provide for adjustment of a roll, a pitch, and a yaw of SRD 1710. For example, adjustment mechanism 1722 of frame 1720 enables SRD 1710 to rotate 1762 about a first axis 1764 relative to mobility system 1730 and underlying surface 1720, and to rotate 1766 about a second axis 1768 relative to mobility system 1730 and underlying surface 1720. Second axis 1768 is orthogonal to first axis 1764 in this example, thereby enabling SRD 1710 to be orientated in a variety of orientations about axes 1764 and 1768. SRD 1710 can be orientated about axes 1764 and 1768 to achieve a desired orientation relative to the Sun and to direct solar energy refracted by the SRD at a target or set of targets. For example, one or more of a plurality of focal points of refracted solar energy can be located at ground level to heat an object (e.g., a container or materials resting upon or below the underlying surface) or to concentrate solar energy to a solar energy device.

Within the example depicted in FIG. 17, frame 1720 provides a multi-axis gimbal configuration by way of support posts 1724, 1726, and 1728 with respect to SRD 1710. In other examples, other suitable configurations can be used to enable rotation of an SRD about one or more axes. It will be understood that frame 1720 is one example of a support structure. In another example, the frame takes the form of an individual post or a tripod, and the SRD is coupled to the post or tripod (e.g., the top or distal end of the post or tripod) by a hinged or ball joint connection that can be selectively locked to retain the SRD at a particular orientation and released to enable an orientation of the SRD to be adjusted. An example of this configuration is described in further detail with reference to FIG. 20. In an example, SRD 1710 is removable from frame 1720 and mobility system 1730, such as at an interface with support posts 1724, 1726, and 1728.

FIG. 18 depicts a mobile solar system 1800 as an example of previously described system 1700 of FIG. 17. In the example depicted in FIG. 17, SRD 1710 is selectively supported above underlying surface 1750 by at least one of a set of wheels 1832 of mobility system 1830 or a set of retractable feet 1822 of frame 1820. Mobility system 1830 in this example may refer to a motorized vehicle or a non-motorized, mechanical vehicle (e.g. a trailer or a rail car) which allows for portability or movement 1760 of the SRD 1710. Feet 1822 can be selectively deployed to contact underlying surface 1750 (e.g., to raise wheels 1832 off of the underlying surface) or retracted from underlying surface 1750 (e.g., to lower wheels 1832 to the underlying surface), enabling system 1800 to be moved to a location of operation using mobility system 1830 while feet 1822 are retracted and then stabilized by deploying feet 1822 at the location operation. Also in this example, frame 1820 enables rotation 1766 or 1762 of SRD 1710 about axis 1768 or axis 1764, respectively using a track system 1824 in place of support post 1728 of FIG. 17. Track system 1824 may incorporate rollers and/or bearings that are confined to a circular or semicircular track of the track system, as an example.

FIG. 19 depicts a mobile solar system 1900 as another example of previously described system 1700 of FIG. 17. In this example, SRD 1710 is again depicted with frame 1820 of FIG. 18. However, in this example, a mobility system 1930 takes the form of a motorized vehicle, such as a truck having a set wheels 1932 that can provide power-assisted movement of the SRD above and across the underlying surface. In an example, features 1934 of support 1820 or features 1936 of mobility system 1930 (e.g., a bed of the truck or a trailer thereof) may define openings through which the SRD can refract solar energy 1940 downward and onto underlying surface 1750. For example, the refracted solar energy may be used to heat roadbed materials during installation of a road. In an example, frame 1820 is configured to be attached to two or more different types of mobility systems. For example, frame 1820 can be attached to mobility system 1930 (e.g., a truck) depicted in FIG. 19 during a first operation, and attached to mobile system 1830 (e.g., a trailer) depicted in FIG. 18 during a second operation.

FIG. 20 depicts another example of a mobile solar system 2000 for an SRD. In this example, a support 2010 in the form of a post is mounted to previously described mobility system 1830. A mounting plate 2012 upon which an SRD can be mounted is rotatably connected to a distal end of support 2010 via an axle 2014 to provide a hinged interface. A pin 2016 rigidly connected to support 2010 passes through a channel 2018 formed within mounting plate 2012 to collectively provide a friction lock that retains mounting plate 2012 (and an SRD mounted thereon) at a fixed orientation. A second instance 2020 of pin 2016 and channel 2018 are additionally provided in this example. Mounting plate 2012 can be rotated about axle 2014 as indicated at 2030 to provide a variety of orientation by overcoming the friction provided by respective instances of pin 2016 and channel 2018. This configuration is another example of an adjustment mechanism 2032 that can be used to provide for adjustment of a roll or a pitch of the solar refraction system. In an example, pin 2016 may take the form of a threaded fastener that can be tightened to increase the friction that inhibits rotation of mounting plate 2012 relative to support 2010, and can be loosened to reduce the friction during adjustment of the mounting plate. Additionally, in FIG. 20, rotation 1766 previously described with reference to FIG. 17 about axis 1768 can be inhibited by tightening a pin 2040 that spans mounting surfaces 2042 and 2044, and can be loosened to enable rotation 1766 about axis 1768. It will be understood that the configuration of support 2010 may take other suitable forms, including a tripod configuration, for example.

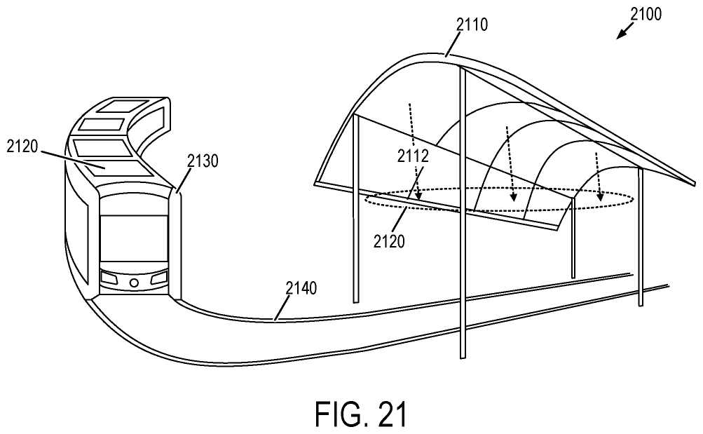

FIG. 21 depicts an example of a solar energy system 2100, including an SRD 2110 that is configured to refract solar energy 2112 onto a solar device 2120 (e.g., photovoltaic cells) located on-board a motorized vehicle 2130 (e.g. a train traveling along a track 2140). In this example, SRD 2110 forms part of a station at which vehicle 2130 stops to at least partially recharge batteries located on-board the vehicle. SRD 2110 forms canopy in this example that refracts solar energy from a larger area than the solar device 2120 to concentrate the refracted solar energy, and thereby increase an amount of available energy for charging.

Examples of the subject matter of the present disclosure are described in the following enumerated paragraphs.

A1. A mobile solar system, comprising: a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to a corresponding lens array sub-assembly of the plurality of lens array sub-assemblies; a frame supporting the solar refraction device above an underlying surface; and a mobility system coupled to the frame to provide for movement of the solar refraction device above and across the underlying surface.

A.2 The system of paragraph A1, wherein the mobility system comprises a motor.

A3. The system of any of paragraphs A1-A2, wherein the frame is configured to be attached to a motorized vehicle.

A4. The system of any of paragraphs A1-A3, wherein the mobility system comprises one or more wheels or continuous treads.

A5. The system of paragraph A4, wherein the frame supporting the solar refraction device further comprises retractable feet.

A6. The system of any of paragraphs A1-A5, wherein the solar refraction device is configured to be removable from the frame.

A7. The system of any of paragraphs A1-A6, further comprising an adjustment mechanism configured to adjust a position of each of one or more lens array sub-assemblies.

A8. The system of any of paragraphs A1-A7, further comprising an adjustment mechanism to provide for adjustment of a roll, a pitch, and a yaw of the solar refraction device.

A9. The system of any of paragraphs A1-A8, wherein one or more of the plurality of focal points are at ground level.

A10. The system of any of paragraphs A1-A9, further comprising a materials bin, and wherein the plurality of focal points are directed at the materials bin.

A11. The system of any of paragraphs A1-A10, wherein a shape of the lens array assembly comprises a 3D parabola or a trough shape.

B1. A refractive solar system, comprising: a solar energy device; and a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to one lens array sub-assembly of the plurality of lens array sub-assemblies, the plurality of focal points being directed at the solar energy device.

B2. The system of paragraph B1, wherein the solar energy device comprises one or more solar tube heating devices.

B3. The system of any of paragraphs B1-B2, wherein the solar energy device comprises one or more solar lighting devices.

B4. The system of any of paragraphs B1-B3, wherein the solar energy device comprises one or more photovoltaic cells.

B5. The system of any of paragraphs B1-B4, wherein the refractive solar system further comprises one or more batteries configured to be charged by the solar energy device.

B6. The system of any of paragraphs B1-B5, further comprising a vehicle; wherein the solar energy device or the solar refraction device is mounted to a vehicle.

C1. A mobile solar system, comprising: a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to a corresponding lens array sub-assembly; a frame supporting the solar refraction device above an underlying surface, the frame comprising retractable feet; an adjustment mechanism to provide for adjustment of at least two degrees of freedom of the solar refraction device; and a first mobility system comprising one or more wheels or continuous tread coupled to the frame to provide power-assisted movement of the solar refraction device above and across the underlying surface.

C2. The system of paragraph C1, wherein the mobility system comprises a motor.

C3. The system of any of paragraphs C1-C2, wherein the frame is configured to be attached to a second mobility system.

C4. The system of paragraph C3, wherein said second mobility system is a mechanical vehicle.

C5. The system of paragraph C3, wherein the second mobility system comprises one or more wheels or continuous treads.

C6. The system of paragraph C5, wherein the retractable feet are configured to be lowered onto the underlying surface to raise the one or more of wheels or continuous treads above the underlying surface.

C7. The system of any of paragraphs C1-C6, wherein the solar refraction device is configured to be removable from the frame.

It will be understood that various aspects or details of the invention may be changed without departing from the scope of the invention. It is not exhaustive and does not limit the claimed inventions to the precise form disclosed. Furthermore, the foregoing description is for the purpose of illustration only, and not for the purpose of limitation. Modifications and variations are possible in light of the above description or may be acquired from practicing the invention. The claims and their equivalents define the scope of the invention.

1. A mobile solar system, comprising:
a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to a corresponding lens array sub-assembly of the plurality of lens array sub-assemblies;
a frame supporting the solar refraction device above an underlying surface; and
a mobility system coupled to the frame to provide for movement of the solar refraction device above and across the underlying surface.

2. The system of claim 1, wherein the mobility system comprises a motor.

3. The system of claim 1, wherein the frame is configured to be attached to a motorized vehicle.

4. The system of claim 1, wherein the mobility system comprises one or more wheels or continuous treads.

5. The system of claim 4, wherein the frame supporting the solar refraction device further comprises retractable feet.

6. The system of claim 1, wherein the solar refraction device is configured to be removable from the frame.

7. The system of claim 1, further comprising an adjustment mechanism configured to adjust a position of each of one or more lens array sub-assemblies.

8. The system of claim 1, further comprising an adjustment mechanism to provide for adjustment of a roll, a pitch, and a yaw of the solar refraction device.

9. The system of claim 1, wherein one or more of the plurality of focal points are at ground level.

10. The system of claim 1, further comprising a materials bin, and wherein the plurality of focal points are directed at the materials bin.

11. The system of claim 1, wherein a shape of the lens array assembly comprises a 3D parabola or a trough shape.

12. A refractive solar system, comprising:
a solar energy device; and
a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to one lens array sub-assembly of the plurality of lens array sub-assemblies, the plurality of focal points being directed at the solar energy device.

13. The system of claim 12, wherein the solar energy device comprises one or more solar tube heating devices.

14. The system of claim 12, wherein the solar energy device comprises one or more solar lighting devices.

15. The system of claim 12, wherein the solar energy device comprises one or more photovoltaic cells.

16. The system of claim 12, wherein the refractive solar system further comprises one or more batteries configured to be charged by the solar energy device.

17. The system of claim 12, further comprising a vehicle; wherein the solar energy device or the solar refraction device is mounted to a vehicle.

18. A mobile solar system, comprising:
a solar refraction device comprising a lens array assembly having a plurality of lens array sub-assemblies, the lens array assembly configured to refract solar energy impinging on the lens array assembly to focus refracted solar energy at a plurality of focal points of the plurality of lens array sub-assemblies, each focal point of the plurality of focal points corresponding to a corresponding lens array sub-assembly;
a frame supporting the solar refraction device above an underlying surface, the frame comprising retractable feet;
an adjustment mechanism to provide for adjustment of at least two degrees of freedom of the solar refraction device; and
a first mobility system comprising one or more wheels or continuous tread coupled to the frame to provide power-assisted movement of the solar refraction device above and across the underlying surface.

19. The system of claim 18, wherein the mobility system comprises a motor.

20. The system of claim 18, wherein the frame is configured to be attached to a second mobility system.

21. The system of claim 20, wherein said second mobility system is a mechanical vehicle.

22. The system of claim 20, wherein the second mobility system comprises one or more wheels or continuous treads.

23. The system of claim 22, wherein the retractable feet are configured to be lowered onto the underlying surface to raise the one or more of wheels or continuous treads above the underlying surface.

24. The system of claim 18, wherein the solar refraction device is configured to be removable from the frame.
